(19) United States
(12) Patent Application Publication
(10) Pub. No.: US 2026/0073993 A1
(43) Pub. Date: Mar. 12, 2026

(54) SEMICONDUCTOR MEMORY DEVICE AND METHOD

(71) Applicant: Kioxia Corporation, Tokyo (JP)

(72) Inventors: Yutai NAGATO, Tokyo (JP); Hideki IGARASHI, Yokohama (JP)

(21) Appl. No.: 19/080,939

(22) Filed: Mar. 17, 2025

(30) Foreign Application Priority Data
Sep. 10, 2024 (JP) 2024-156986

(51) Int. Cl. G11C 16/16; G11C 16/12; G11C 16/26

(52) U.S. Cl. CPC G11C 16/16; G11C 16/12; G11C 16/26

(57) ABSTRACT

A semiconductor memory device includes a bit line, memory transistors connected to the bit line, a source line connected to the transistors, a word line electrically connected to a memory transistor, a voltage generation circuit configured to generate voltages to be applied to the lines, and a control circuit configured to control the voltage generation circuit. The control circuit is configured to: upon receipt of a command for erasing data, determine: one of program modes that was previously used based on a distribution pattern of threshold voltages of the transistors, and one of the program modes to be used, and control the voltage generation circuit based on said one of program modes that was previously used and the program mode to be used to erase the data.

### CROSS-REFERENCE TO RELATED APPLICATION

This application is based upon and claims the benefit of priority from Japanese Patent Application No. 2024-156986, filed Sep. 10, 2024, the entire contents of which are incorporated herein by reference.

### FIELD

Embodiments described herein relate generally to a semiconductor memory device and a method.

### BACKGROUND

Data erase conditions of a semiconductor memory device such as a NAND memory are optimized for each of Single-Level Cell (SLC) and Quad-Level Cell (QLC), for example. Meanwhile, in some cases, both SLC and QLC are used for the same block. For example, SLC or QLC rewrite is performed after QLC or SLC write. In this case, the data erase conditions may not be optimized in consideration of a distribution pattern of a threshold voltage distribution before rewrite and the distribution pattern after the rewrite.

### BRIEF DESCRIPTION OF THE DRAWINGS

FIG. 1 is a schematic block diagram illustrating a semiconductor memory device according to a first embodiment.

FIG. 2 is a schematic circuit diagram illustrating the semiconductor memory device according to the first embodiment.

FIG. 3 is a schematic block diagram illustrating the semiconductor memory device according to the first embodiment.

FIG. 4 is a schematic circuit diagram illustrating the semiconductor memory device according to the first embodiment.

FIG. 5 is a schematic perspective view illustrating a structure of the semiconductor memory device according to the first embodiment.

FIG. 6 is a schematic enlarged view of a part of the semiconductor memory device indicated by A in FIG. 5.

FIG. 7 is a schematic flow diagram illustrating an operation of the semiconductor memory device according to the first embodiment.

FIG. 8 is a schematic equivalent circuit diagram illustrating the operation of the semiconductor memory device according to the first embodiment.

FIG. 9 is a schematic diagram illustrating information on a prefix command according to the first embodiment.

FIG. 10 is a schematic diagram of a distribution pattern before an erase operation according to the first embodiment.

### DETAILED DESCRIPTION

Embodiments provide a semiconductor memory device that can more appropriately perform an erase operation.

In general, according to one embodiment, a semiconductor memory device comprises a bit line; a plurality of memory transistors electrically connected to the bit line; a source line electrically connected to the memory transistors; a word line electrically connected to a gate electrode of one of the memory transistors; a voltage generation circuit configured to generate voltages to be applied to the bit line, the source line, and the word line; and a control circuit configured to control the voltage generation circuit to generate the voltages. The control circuit is further configured to: upon receipt of a command for erasing data stored in the memory transistors, determine: one of program modes that was previously used to write or erase data in the memory transistors based on a distribution pattern of threshold voltages of the memory transistors, and one of the program modes to be used to erase the data, and control the voltage generation circuit to generate a pre-program voltage to be applied to the word line and an erase voltage to be applied to at least one of the bit line and the source line based on said one of program modes that was previously used and the program mode to be used to erase the data.

Hereinafter, embodiments of the present disclosure will be described with reference to the drawings. The embodiments described below do not limit the present disclosure. In the specification and drawings, the same elements as those described above with respect to the existing drawings are given the same reference numerals, and detailed description thereof will be omitted as appropriate.

In addition, in this specification, a predetermined direction parallel to a front surface of a substrate is referred to as the X-direction, a direction parallel to the front surface of the substrate and perpendicular to the X-direction is referred to as the Y-direction, and a direction perpendicular to the front surface of the substrate is referred to as the Z-direction.

In addition, in this specification, a direction along a predetermined surface may be referred to as a first direction, a direction intersecting the first direction along this predetermined surface may be referred to as a second direction, and a direction intersecting the predetermined surface may be referred to as a third direction. The first direction, the second direction, and the third direction may or may not correspond to any of the X-direction, the Y-direction, and the Z-direction.

In this specification, expressions such as “above” and “below” are based on the substrate. For example, a direction away from the substrate along the first direction is referred to as “above”, and a direction toward the substrate along the first direction is referred to as “below”. In addition, when a lower surface or lower end of a certain element is referred to, it means a surface or end of the element on the substrate side, and when an upper surface or upper end of a certain element is referred to, it means a surface or end of the element on the opposite side to the substrate. In addition, a surface intersecting the second direction or the third direction is referred to as a side surface or the like.

In this specification, when a “semiconductor memory device” is referred to, it may mean a memory die, or a memory system including a control die, such as a memory chip, a memory card, or an SSD. In addition, it may also refer to a device that includes a host computer, such as a smartphone, tablet terminal, or personal computer.

In this specification, when it is stated that a first element is “electrically connected” to a second element, the first element may be directly connected to the second element, or the first element may be connected to the second element via wiring, a semiconductor member, a transistor, or the like. For example, when three transistors are connected in series, even if the second transistor is in an OFF state, the first transistor is “electrically connected” to the third transistor.

In addition, in this specification, when it is stated that a first element is “connected between” a second element and a third element, it may mean that the first element, the second element, and the third element are connected in series, and the first element is provided in a current path of the second element and the third element.

In addition, in this specification, when it is stated that a circuit or the like “electrically connects” two wirings to each other, it may mean, for example, that the circuit or the like includes a transistor, that the transistor or the like is provided in a current path between the two wirings, and that the transistor or the like is turned to an ON state.

### First Embodiment

### Configuration

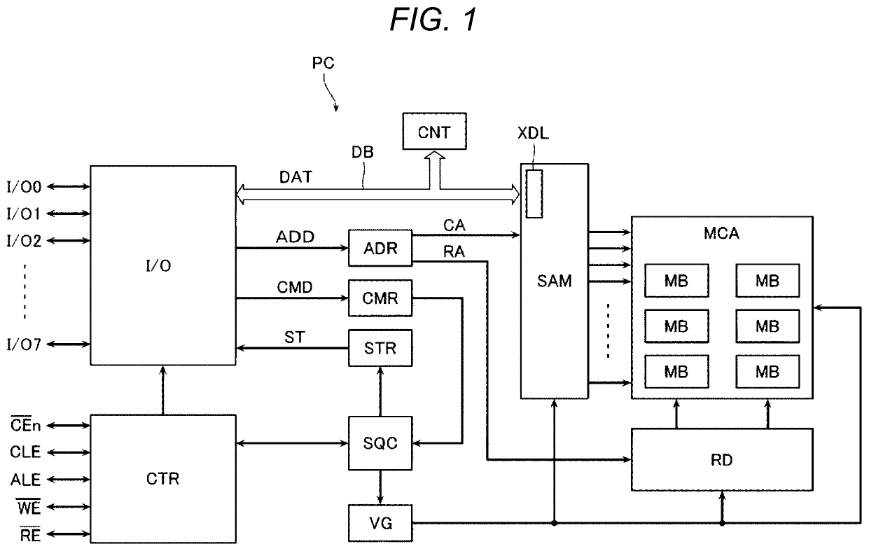

FIG. 1 is a schematic equivalent circuit diagram illustrating a semiconductor memory device according to a first embodiment.

The semiconductor memory device according to the first embodiment includes a memory cell array MCA and a peripheral circuit PC that controls the memory cell array MCA.

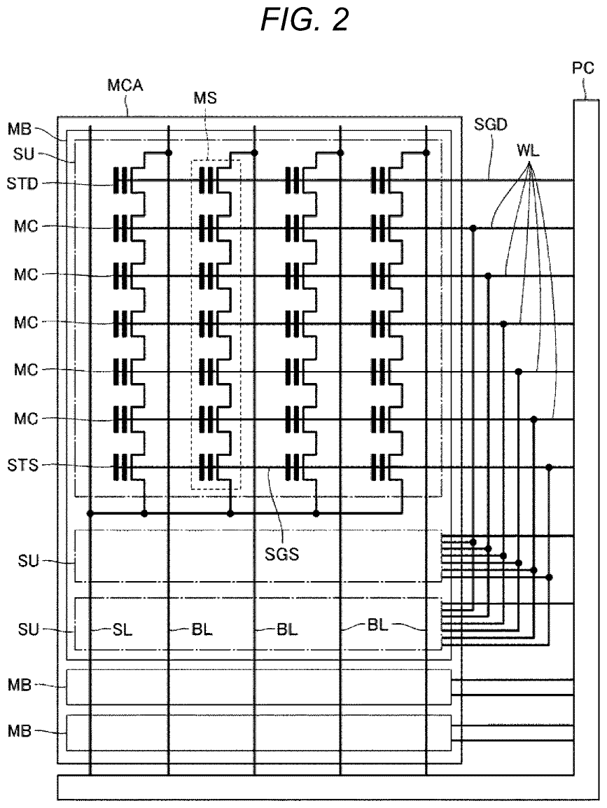

The memory cell array MCA includes a plurality of memory blocks MB. As illustrated in FIG. 2, each of the memory blocks MB includes a plurality of string units SU. Each of the plurality of string units SU includes a plurality of memory strings MS. One end of each of the plurality of memory strings MS is connected to a peripheral circuit PC via a bit line BL. The other end of each of the plurality of memory strings MS is connected to the peripheral circuit PC via a common source line SL.

The memory string MS includes a drain select transistor STD, a plurality of memory cells MC, and a source select transistor STS that are connected in series between the bit line BL and the source line SL. Hereinafter, the drain select transistor STD and the source select transistor STS may be simply referred to as select transistors STD and STS.

The memory cell MC is a field effect transistor including a semiconductor layer functioning as a channel region, a gate insulating film including a charge storage film, and a gate electrode. A threshold voltage of the memory cell MC changes depending on an amount of charge in the charge storage film. A word line WL is connected to each of gate electrodes of the plurality of memory cells MC corresponding to one memory string MS. Each of these word lines WL is commonly connected to all the memory strings MS in one memory block MB.

The select transistors STD and STS are field effect transistors each including a semiconductor layer functioning as a channel region, a gate insulating film, and a gate electrode. Select gate lines SGD and SGS are connected to the gate electrodes of the select transistors STD and STS, respectively. The drain select line SGD is provided corresponding to the string unit SU and is commonly connected to all the memory strings MS in one string unit SU. The source select line SGS is commonly connected to all the memory strings MS in one memory block MB.

As illustrated in FIG. 1, the peripheral circuit PC includes a row decoder RD, a sense amplifier module SAM, a voltage generation circuit VG, a count circuit CNT, and a sequencer SQC. The peripheral circuit PC also includes an address register ADR, a command register CMR, and a status register STR. In addition, the peripheral circuit PC includes an input and output control circuit I/O, and a logic circuit CTR.

The row decoder RD includes, for example, a decode circuit and a switch circuit. The decode circuit decodes a row address RA stored in the address register ADR. The switch circuit electrically connects the word line WL and the select gate lines SGD and SGS corresponding to the row address RA to a corresponding voltage supply line according to an output signal of the decode circuit.

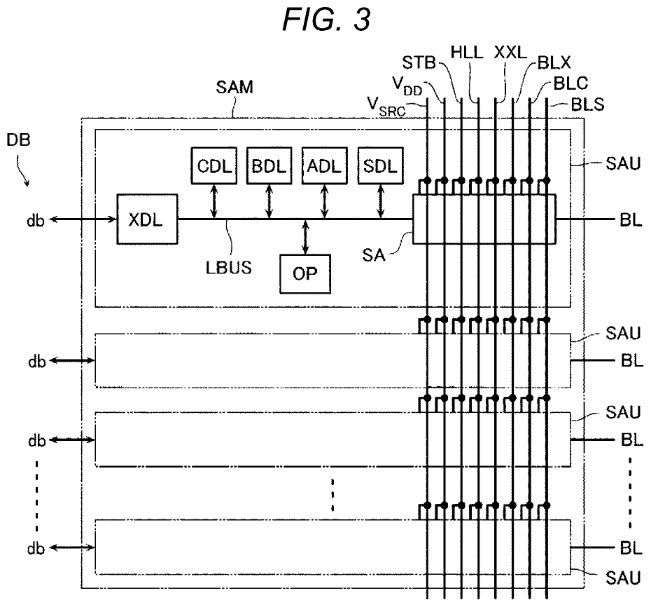

As illustrated in FIG. 3, the sense amplifier module SAM includes a plurality of sense amplifier units SAU corresponding to a plurality of bit lines BL. The sense amplifier unit SAU includes a sense amplifier SA connected to the bit line BL, data latches SDL, ADL, BDL, CDL, and XDL, the logic circuit OP, and a wiring LBUS connected to these components.

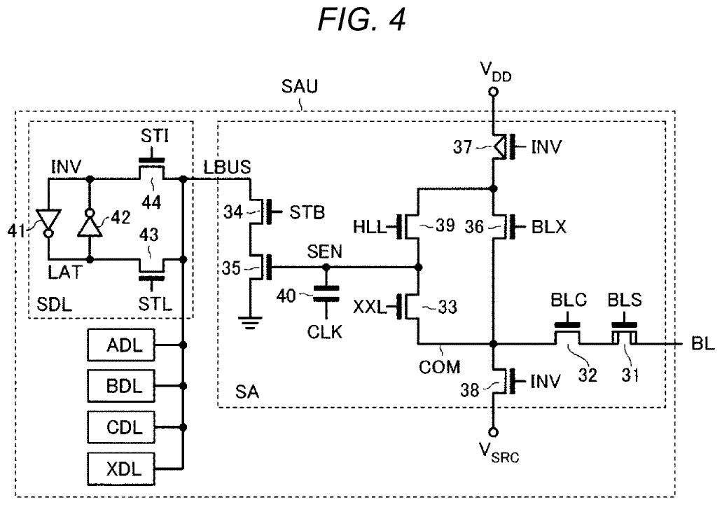

As illustrated in FIG. 4, the sense amplifier SA includes a breakdown voltage transistor 31, a clamp transistor 32, a node COM, and a discharge transistor 33 connected in series between the bit line BL and a sense node SEN. In addition, the sense amplifier SA includes a switch transistor 34 and a sense transistor 35 connected in series between the wiring LBUS and a ground voltage supply line. The ground voltage supply line is connected to a pad electrode for supplying a ground voltage VSS.

The breakdown voltage transistor 31 is an NMOS type breakdown voltage transistor. The breakdown voltage transistor 31 protects the sense amplifier SA, for example, when a relatively large voltage is applied to the source line SL (FIG. 2). A control signal from the sequencer SQC is supplied to a gate electrode of the breakdown voltage transistor 31 via a signal line BLS.

The clamp transistor 32 is an NMOS type transistor. The clamp transistor 32 controls a voltage of the bit line BL. A control signal from the sequencer SQC is supplied to a gate electrode of the clamp transistor 32 via a signal line BLC.

The node COM is connected to a charge transistor 36, a charge transistor 37, and a power supply voltage supply line VDD. The power supply voltage supply line VDD is connected to a pad electrode for supplying a power supply voltage. In addition, the node COM is connected to a voltage supply line VSRC via a discharge transistor 38. The charge transistor 36 and the discharge transistor 38 are NMOS type transistors. The charge transistor 37 is a PMOS type transistor. A control signal from the sequencer SQC is supplied to a gate electrode of the charge transistor 36 via a signal line BLX. Each of gate electrodes of the charge transistor 37 and the discharge transistor 38 are connected to a node INV of the data latch SDL.

The discharge transistor 33 is an NMOS type transistor. The discharge transistor 33 discharges electrical charge of the sense node SEN. A control signal from the sequencer SQC is supplied to a gate electrode of the discharge transistor 33 via a signal line XXL.

The sense node SEN is connected to the power supply voltage supply line VDD via a charge transistor 39 and the charge transistor 37. In addition, the sense node SEN is connected to a signal line CLK via a capacitor 40. A control signal is supplied to the signal line CLK from the sequencer SQC. The charge transistor 39 is an NMOS type transistor. A control signal from the sequencer SQC is supplied to a gate electrode of the charge transistor 39 via a signal line HLL.

The switch transistor 34 is an NMOS type transistor. The switch transistor 34 electrically connects the wiring LBUS and the sense transistor 35 to each other. A control signal from the sequencer SQC is supplied to a gate electrode of the switch transistor 34 via a signal line STB.

The sense transistor 35 is an NMOS type transistor. The sense transistor 35 releases or maintains electrical charge in the wiring LBUS depending on a voltage of the sense node SEN. A gate electrode of the sense transistor 35 is connected to the sense node SEN.

As illustrated in FIG. 3, in the first embodiment, the signal lines BLS, BLC, BLX, XXL, HLL, and STB are each commonly connected between all sense amplifier units SAU in the sense amplifier module SAM. In the first embodiment, the power supply voltage supply line VDD and the voltage supply line VSRC are each commonly connected between all sense amplifier units SAU in the sense amplifier module SAM.

As illustrated in FIG. 4, the data latch SDL includes a node LAT and the node INV, inverters 41 and 42 connected in parallel between the node LAT and the node INV, a switch transistor 43 connected between the node LAT and the wiring LBUS, and a switch transistor 44 connected between the node INV and the wiring LBUS. An output terminal of the inverter 41 and an input terminal of the inverter 42 are connected to the node LAT. An input terminal of the inverter 41 and an output terminal of the inverter 42 are connected to the node INV. Although not illustrated, the data latches ADL, BDL, CDL, and XDL have the same configuration as that of the data latch SDL.

For example, data stored in the data latch SDL is transferred to the data latches ADL, BDL, and CDL as appropriate. The logic circuit OP (FIG. 3) performs logical operations such as AND, OR, and XOR on the data in the data latches ADL, BDL, and CDL to calculate user data allocated to the memory cell MC.

The data latch XDL is connected to the wiring LBUS and a wiring db (FIG. 3) that constitutes a bus DB. For example, user data to be written to the memory cell MC or user data read from the memory cell MC is stored in the data latch XDL.

In addition, the sense amplifier module SAM includes a decode circuit and a switch circuit (not illustrated). The decode circuit decodes a column address CA stored in the address register ADR (FIG. 1). The switch circuit electrically connects the data latch XDL corresponding to the column address CA to the bus DB according to an output signal of the decode circuit.

A voltage generation circuit VG (FIG. 1) includes, for example, a step-up circuit such as a charge pump circuit connected to the power supply voltage supply line VDD and the ground voltage supply line, a step-down circuit such as a regulator, and a plurality of voltage supply lines (not illustrated). The voltage generation circuit VG generates a plurality of operating voltages to be applied to the bit line BL, the source line SL, the word lines WL, and the select gate lines SGD and SGS during a read operation, write operation, and erase operation for the memory cell array MCA in accordance with an internal control signal from the sequencer SQC, and outputs the generated voltages simultaneously from the plurality of voltage supply lines.

The count circuit CNT is connected to the bus DB and counts the number of data pieces indicating “1” and the number of data pieces indicating “0” among data pieces stored in the data latch XDL. In addition, the count circuit CNT is able to thin out and count the number of data pieces indicating “1” or “0”. That is, instead of counting the number of data pieces stored in all the data latches XDL in the sense amplifier module SAM, the count circuit CNT is able to count the number of memory cells MC based on only the data pieces stored in some of the data latches XDL.

The sequencer SQC sequentially decodes command data CMD stored in the command register CMR and outputs the command data CMD from a plurality of signal lines to output the internal control signal to the row decoder RD, the sense amplifier module SAM, the voltage generation circuit VG, and the count circuit CNT. In addition, the sequencer SQC outputs status data indicating its own state to the status register STR as appropriate. For example, in the execution of the write operation or the erase operation, information indicating whether the write operation or the erase operation is normally finished is output as status data.

The input and output control circuit I/O includes data input and output terminals I/O0 to I/O7, a shift register connected to the data input and output terminals I/O0 to I/O7, and a FIFO buffer connected to the shift register. The input and output control circuit I/O has eight pad electrodes, and outputs data input from the data input and output terminals I/O0 to I/O7 to the data latch XDL, address register ADR, or command register CMR in the sense amplifier module SAM according to an internal control signal from the logic circuit CTR. In addition, the input and output control circuit I/O outputs data input from the data latch XDL or the status register STR to the data input and output terminals I/O0 to I/O7.

The logic circuit CTR receives an external control signal from a control die CD via external control terminals/CEn, CLE, ALE, /WE, and /RE, and outputs an internal control signal to the input and output control circuit I/O according to the external control signal.

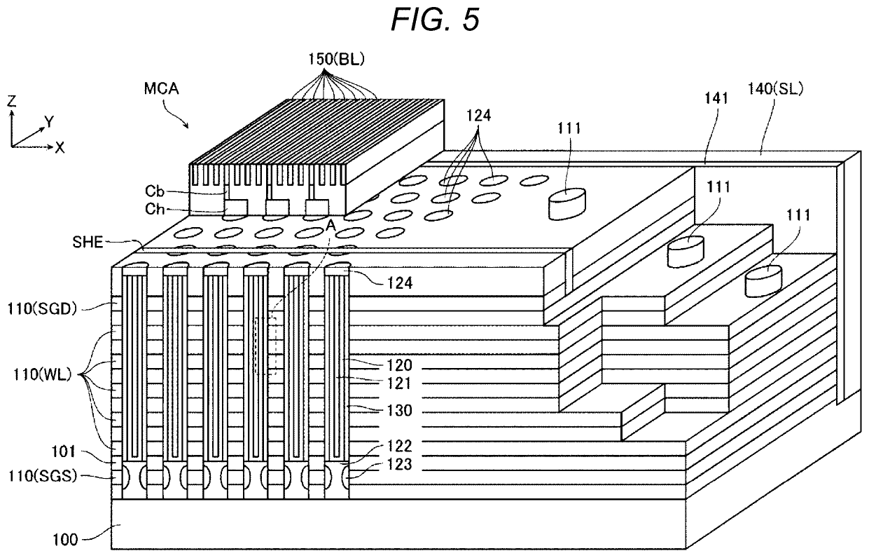

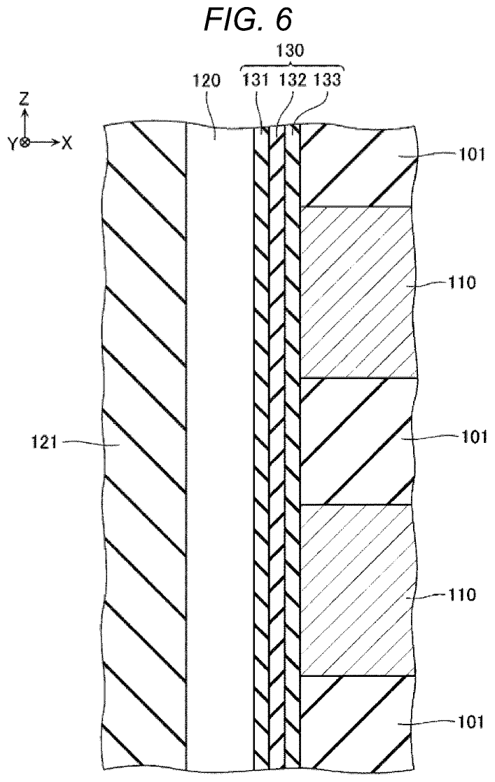

Next, a structure of the semiconductor memory device according to the first embodiment will be described with reference to FIG. 5 and FIG. 6. FIG. 5 is a schematic perspective view illustrating a structure of the semiconductor memory device according to the first embodiment. FIG. 6 is a schematic enlarged view of a part of the semiconductor memory device indicated by A in FIG. 5.

As illustrated in FIG. 5, the semiconductor memory device according to the first embodiment includes a semiconductor substrate 100, a plurality of conductive layers 110 provided above the semiconductor substrate 100, a plurality of semiconductor layers 120, a plurality of gate insulating films 130 each provided between the plurality of conductive layers 110 and the plurality of semiconductor layers 120, a conductive layer 140 connected to a front surface of the semiconductor substrate 100, and a conductive layer 150 connected to an upper end of the semiconductor layer 120.

The semiconductor substrate 100 is, for example, a semiconductor substrate made of a material such as single crystal silicon (Si) containing P-type impurities such as boron (B). An N-type well containing N-type impurities such as phosphorus (P) is provided on a part of the front surface of the semiconductor substrate 100. In addition, a P-type well containing P-type impurities such as boron (B) is provided on a part of a front surface of the N-type well.

The conductive layer 110 is a substantially plate-like conductive layer extending in the X-direction, and a plurality of conductive layers 110 are arranged in the Z-direction. Each conductive layer 110 may include, for example, a stacked film of titanium nitride (TiN) and tungsten (W), or may contain polycrystalline silicon containing impurities such as phosphorus or boron. In addition, each insulating layer 101 made of a material such as silicon oxide (SiO₂) is provided between the conductive layers 110.

Among the plurality of conductive layers 110, one or more conductive layers 110 located at the lowest layer function as the source select line SGS (FIG. 2) and gate electrodes of a plurality of source select transistors STS connected thereto. In addition, a plurality of conductive layers 110 located above the one or more conductive layers 110 function as a word line WL (FIG. 2) and gate electrodes of a plurality of memory cells MC connected thereto (FIG. 2). In addition, one or more conductive layers 110 located above the plurality of conductive layers 110 function as the drain select line SGD and gate electrodes of the plurality of drain select transistors STD (FIG. 2) connected thereto. The conductive layer 110 functioning as the drain select transistor STD is divided in the Y-direction via an insulating layer SHE extending in the X-direction.

A plurality of semiconductor layers 120 are arranged in the X-direction and the Y-direction. Each semiconductor layer 120 is made of, for example, a semiconductor film containing a material such as undoped polycrystalline silicon (Si). The semiconductor layer 120 has a substantially cylindrical shape, and an insulating film 121 such as silicon oxide is provided in a center portion thereof. In addition, an outer peripheral surface of each semiconductor layer 120 is surrounded by the conductive layer 110. A lower end portion of the semiconductor layer 120 is connected to the P-type well of the semiconductor substrate 100 via a semiconductor layer 122 made of a material such as undoped single crystal silicon. The semiconductor layer 122 faces the conductive layer 110 via an insulating layer 123 made of a material such as silicon oxide. An upper end portion of the semiconductor layer 120 is connected to the bit line BL via a semiconductor layer 124, which contains N-type impurities such as phosphorus (P), and contacts Ch and Cb. Each semiconductor layer 120 functions as a channel region of a plurality of memory cells MC and drain select transistor STD in one memory string MS (FIG. 2). The semiconductor layer 122 functions as a channel region of a part of the source select transistor STS.

As illustrated in FIG. 6, for example, the gate insulating film 130 includes a tunnel insulating film 131, a charge storage film 132, and a block insulating film 133 that are stacked between the semiconductor layer 120 and the conductive layer 110. The tunnel insulating film 131 and the block insulating film 133 are, for example, insulating films made of a material such as silicon oxide. The charge storage film 132 is, for example, a film capable of storing electric charge and made of a material such as silicon nitride (SiN). The tunnel insulating film 131, the charge storage film 132, and the block insulating film 133 have a substantially cylindrical shape and extend in the Z-direction along the outer circumferential surface of the semiconductor layer 120.

Although FIG. 6 illustrates a structure in which the gate insulating film 130 includes the charge storage film 132 made of silicon nitride or the like, the gate insulating film 130 may include, for example, a floating gate made of polycrystalline silicon containing N-type or P-type impurities.

The conductive layer 140 is, for example, as illustrated in FIG. 5, a substantially plate-like conductive layer extending in the X-direction and the Z-direction. The conductive layer 140 may include, for example, a stacked film made of titanium nitride (TiN) and tungsten (W), or may contain polycrystalline silicon containing impurities such as phosphorus. In addition, an insulating layer 141 is provided between the conductive layer 140 and the conductive layer 110. The conductive layer 140 functions as the source line SL.

Each conductive layer 150 extends in the Y-direction, and a plurality of conductive layers 150 are arranged in the X-direction. Each conductive layer 150 may include a stacked film made of titanium nitride (TiN) and copper (Cu), or may contain polycrystalline silicon containing impurities such as phosphorus. The conductive layer 150 functions as the bit line BL.

### Erase Operation

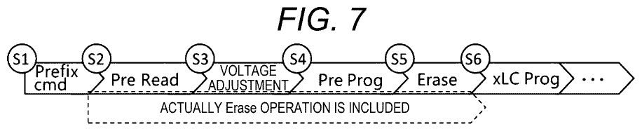

Next, an erase operation of the semiconductor memory device according to the first embodiment will be described with reference to FIG. 7. FIG. 7 is a schematic flow diagram illustrating the operation of the semiconductor memory device according to the first embodiment.

In step S1, a prefix command PFC (Prefix cmd) is acquired.

In step S2, a pre-read operation is executed. The pre-read operation is basically executed in the same manner as a read operation. Details of the pre-read operation will be described below.

In step S3, adjustment of a voltage needed for subsequent steps S4 and S5 is performed based on the prefix command PFC and a result of the pre-read operation. Details of the voltage adjustment will be described below.

In step S4, a pre-program (Pre Prog) operation is executed. The pre-program operation is executed in the same manner as a program operation in the write operation, for example. In step S4, a pre-program voltage VPGM adjusted in step S3 is applied.

In step S5, an erase voltage application operation is executed. In the erase voltage application operation, a voltage is applied to the memory cell MC and the like. For example, in the erase voltage application operation, an erase voltage VERA is applied to the bit line BL. The erase voltage VERA is greater than a write pass voltage VPASS.

In addition, for example, in the erase voltage application operation, an OFF voltage VOFF is applied to the drain select line SGD, and an ON voltage VON″ is applied to the source select line SGS. The ON voltage VON″ has a magnitude such that, for example, a hole channel is formed in the channel region of the source select transistor STS and the source select transistor STS is turned into an ON state.

In addition, for example, in the erase voltage application operation, a ground voltage VSS is applied to all the word lines WL. As a result, holes are accumulated in the charge storage film 132 (FIG. 6) of the memory cell MC, and a threshold voltage of the memory cell MC is reduced.

In step S6, a write (xLC Prog) operation is executed in a certain program mode.

In practice, steps S2 to S5 are included in the erase operation.

Next, the voltage adjustment in step S3 will be described in detail.

In some cases, both Single-Level Cell (SLC) and Quad-Level Cell (QLC) are used for the same memory block MB. For example, in some cases, data erase is performed and SLC write is performed (SLC rewrite) after QLC write. That is, data can be written to a memory cell by switching the memory cell to one of a plurality of modes in which data is written with different numbers of bits with respect to the same memory cell MC.

In the following, details of erase conditions in consideration of a distribution pattern of threshold voltage distribution before rewrite and a distribution pattern after the rewrite will be described.

At least one of the pre-program voltage VPGM and the erase voltage VERA is adjusted based on which of a plurality of modes the distribution pattern of the threshold voltage distribution of the memory cell MC before the pre-program operation (i.e., erase operation) is in and on which of the plurality of modes the erase operation is in. By adjusting at least one of the pre-program voltage VPGM and the erase voltage VERA, the erase operation can be performed more appropriately.

More specifically, at least one of the pre-program voltage VPGM and the erase voltage VERA is adjusted based on whether the distribution pattern before the pre-program operation is an erase distribution or a write distribution in any one of the plurality of modes, and on which of the plurality of modes the erase operation is in.

The distribution pattern before the erase operation is determined by the execution of the pre-read operation. Which of the plurality of modes the erase operation is in is determined based on the prefix command sent before the erase command. The pre-read operation is an operation for determining the distribution pattern before the pre-program operation.

In the pre-program operation, a predetermined write voltage (hereinafter referred to as the pre-program voltage VPGM) is applied to perform weak writing to the memory cell MC before the erase voltage VERA is applied.

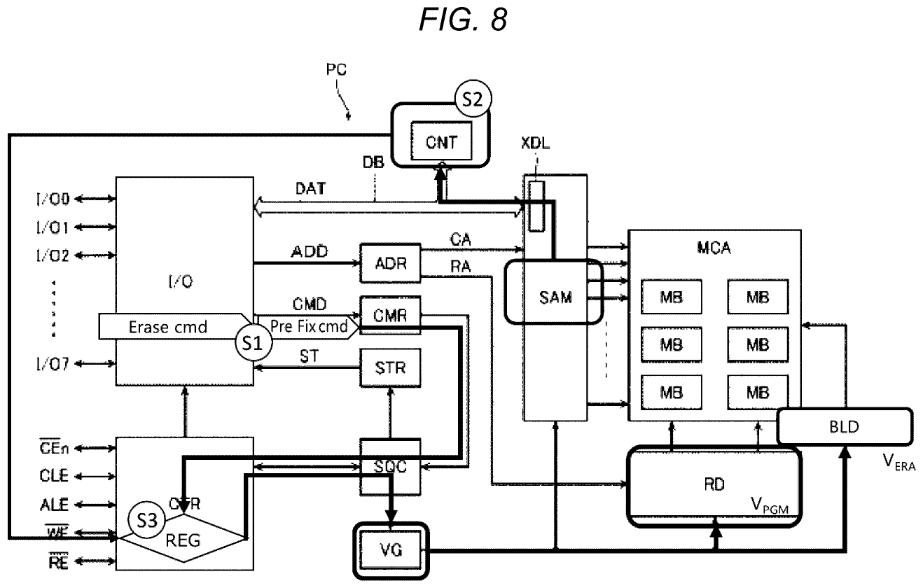

FIG. 8 is a schematic equivalent circuit diagram illustrating the operation of the semiconductor memory device according to the first embodiment. The description of the same elements as that illustrated in FIG. 1 will be omitted.

The logic circuit CTR includes a register circuit REG. The register circuit REG stores which of a plurality of modes a distribution pattern before the pre-program operation is in, and which of the plurality of modes the erase operation is in. That is, the register circuit REG stores the result of the pre-read operation (hereinafter also referred to as the distribution determination result) and information on the prefix command PFC. Details of the result of the pre-read operation and information on the prefix command PFC will be described below. The register circuit REG is not limited to being located in the logic circuit CTR, and may be provided at another position.

The semiconductor memory device further includes a control circuit BLD. The control circuit BLD applies the erase voltage VERA to the bit line BL. The erase voltage VERA may be applied to at least one of the bit line BL and the source line SL.

In step S1, the input and output control circuit I/O receives an erase command as an input. The command register CMR acquires information on the prefix command PFC. The information on the prefix command PFC includes information on a distribution pattern to be written next thereto. The information on the prefix command PFC is sent to the register circuit REG of the logic circuit CTR via the sequencer SQC. The register circuit REG stores the information on the prefix command PFC.

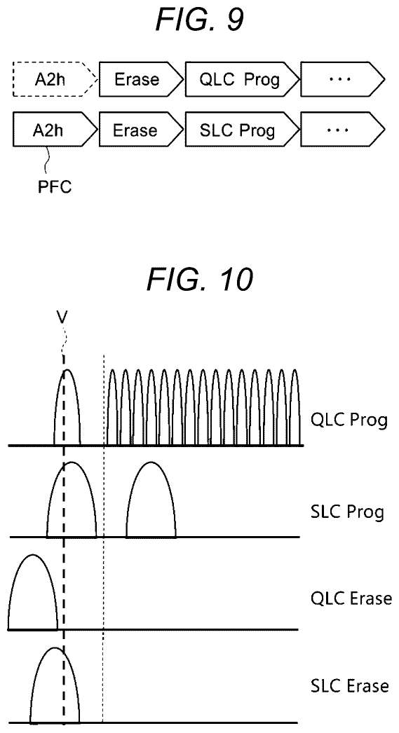

FIG. 9 is a schematic diagram illustrating the information on the prefix command PFC according to the first embodiment. The upper part of FIG. 9 illustrates a case where the QLC rewrite is performed. The lower part of FIG. 9 illustrates a case where the SLC rewrite is performed.

The write operations (QLC Prog and SLC Prog) are often set with an erase operation (Erase) before the write operation from the viewpoint of memory cell reliability, but this is not always the case. The erase operation (Erase) illustrated in FIG. 9 includes steps S2 to S5 illustrated in FIG. 7.

In the first embodiment, it is assumed that when a write operation is performed in the QLC, an erase operation is performed in the QLC, and when the write operation is performed in the SLC, the erase operation is performed in the SLC. The erase conditions, such as the pre-program voltage VPGM and the erase voltage VERA, are set in the QLC or SLC set.

The prefix command PFC is a command before the erase command (Erase in FIG. 9). The type of the prefix command varies depending on the distribution pattern to be written next thereto.

An A2h command is an example of the prefix command. In the example illustrated in FIG. 9, when the QLC rewrite is performed, the A2h command is not inserted before the erase command. On the other hand, when the SLC rewrite is performed, the A2h command is inserted before the erase command. That is, the distribution pattern to be written next thereto can be determined depending on the presence or absence of the A2h command.

In step S2, the sense amplifier module SAM and the count circuit CNT perform a pre-read operation. As a result, the distribution pattern before the erase operation can be determined or identified. The distribution determination result of the pre-read operation is sent to the register circuit REG of the logic circuit CTR. The register circuit REG stores the distribution determination result of the pre-read operation.

FIG. 10 is a schematic diagram of the distribution patterns before the erase operation according to the first embodiment. FIG. 10 shows a write distribution in QLC, a write distribution in SLC, an erase distribution in QLC, and an erase distribution in SLC from the top. Reading by the pre-read operation is performed with a pre-read voltage VPR shown by a broken line. The pre-read voltage VPR is variable.

By the pre-read operation, whether the threshold voltage distribution is one of four distribution patterns can be determined. That is, the distribution determination result includes not only whether the threshold voltage distribution is the write distribution or the erase distribution, but also whether the write distribution or the erase distribution is in SLC or QLC mode.

In step S3, the logic circuit CTR generates an internal control signal for adjusting at least one of the pre-program voltage VPGM and the erase voltage VERA based on the information on the prefix command PFC and the distribution determination result of the pre-program operation, and sends the internal control signal to the voltage generation circuit VG.

The voltage generation circuit VG controls the pre-program voltage VPGM and the erase voltage VERA according to the internal control signal. The voltage generation circuit VG adjusts at least one of the pre-program voltage VPGM and the erase voltage VERA based on the information on the prefix command PFC and the result of the pre-read operation. As a result, the erase operation can be performed more appropriately. Details of the adjustment will be described below.

In step S4, the row decoder RD transfers the pre-program voltage VPGM to a selected block.

In step S5, the control circuit BLD transfers the erase voltage VERA to the selected block.

Next, the adjustment of the pre-program voltage VPGM and erase voltage VERA will be described.

When there is a concern about shallow erase after the write operation, at least one of lowering the pre-program voltage VPGM and raising the erase voltage VERA is performed. When there is a concern about deep erase after the write operation, at least one of raising the pre-program voltage VPGM and lowering the erase voltage VERA is performed.

When the result of the pre-read operation is the erase distribution, the pre-program voltage VPGM may be adjusted. When the result of the pre-read operation is the write distribution, the erase voltage VERA may be adjusted.

When the erase operation and the write operation are performed in SLC for the QLC write distribution, there is a concern about shallow erase. In this case, the result of the pre-read operation is the QLC write distribution. The erase voltage VERA is adjusted to be 1.0 V higher than a set value, for example. When the erase operation is performed in QLC for the SLC write distribution, there is a concern about deep erase. In this case, the result of the pre-read operation is the SLC write distribution. The erase voltage VERA is adjusted to be 0.5 V lower than the set value, for example.

At least one of the pre-program voltage VPGM and the erase voltage VERA may be zero. When the pre-program voltage VPGM is zero, no pre-program operation is performed. When the erase voltage VERA is zero, no erase operation is performed.

As described above, according to the first embodiment, at least one of the pre-program voltage VPGM and the erase voltage VERA is adjusted based on which of the plurality of modes the distribution pattern of the threshold voltage distribution of the memory cell MC before the erase operation is in and on which of the plurality of modes the erase operation is in. By adjusting at least one of the pre-program voltage VPGM and the erase voltage VERA, the erase operation can be performed more appropriately. As a result, the reliability of the write distribution can be improved. In addition, the degradation of a cell due to over-erasure can be prevented.

The plurality of modes may include, for example, a Triple-Level Cell (TLC) or the like instead of the QLC. In addition, the plurality of modes are not limited to two modes, and may be three or more modes. The plurality of modes may include, for example, the SLC, the TLC, and the QLC.

The first embodiment is not limited to the case where the plurality of modes are used for the same block, but may be applied to, for example, the case where an erase operation is performed for a distribution pattern that occurs when the order of operations or the like is changed, for example.

Next, a comparative example will be described in which whether the distribution pattern before the erase operation is SLC or QLC is not taken into consideration. In this case, in the pre-read operation, it is determined whether the distribution is the write distribution or the erase distribution.

When the erase operation in SLC is performed on an erase distribution in QLC, a weak pre-program operation for SLC is performed from a deeply erased state, and then a shallow erase is performed, which may cause a concern of deep erase.

In addition, when the erase operation in SLC is performed on the write distribution in QLC, there is a concern about shallow erase because the erase is performed shallowly on a highly written threshold voltage. When the erase operation in QLC is performed on the write distribution in SLC, there is a concern about deep erase because the erase is performed deeply on a shallowly written threshold voltage.

In contrast, in the first embodiment, the erase conditions are adjusted in consideration of the distribution patterns before and after the rewrite. As a result, the reliability of write distribution can be improved. In addition, the degradation of a cell due to over-erasure can be prevented.

At least a part of a data processing method in the semiconductor memory device according to the first embodiment may be performed by hardware or software. When the part of the data processing method is performed by software, a program that implements at least some of the functions of the data processing method may be stored in a recording medium such as a flexible disk or a CD-ROM, and may be read and executed by a computer. The recording medium is not limited to a removable one such as a magnetic disk or an optical disk, but may also be a fixed type recording medium such as a hard disk device or memory. In addition, the program that implements at least some of the functions of the data processing method may be distributed via a communication line (including wireless communication) such as the Internet. Furthermore, the program may be distributed in an encrypted, modulated or compressed state via a wired line or wireless line such as the Internet, or stored in a recording medium.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a bit line;
a plurality of memory transistors electrically connected to the bit line;
a source line electrically connected to the memory transistors;
a word line electrically connected to a gate electrode of one of the memory transistors;
a voltage generation circuit configured to generate voltages to be applied to the bit line, the source line, and the word line; and
a control circuit configured to control the voltage generation circuit to generate the voltages, wherein
the control circuit is further configured to:
upon receipt of a command for erasing data stored in the memory transistors, determine:
one of program modes that was previously used to write or erase data in the memory transistors based on a distribution pattern of threshold voltages of the memory transistors, and
one of the program modes to be used to erase the data, and
control the voltage generation circuit to generate a pre-program voltage to be applied to the word line and an erase voltage to be applied to at least one of the bit line and the source line based on said one of program modes that was previously used and the program mode to be used to erase the data.

2. The semiconductor memory device according to claim 1, wherein
the control circuit is configured to determine whether the distribution pattern is an erase distribution pattern in which data was erased using one of the program modes or a write distribution pattern in which data was written using one of the program modes.

3. The semiconductor memory device according to claim 1, further comprising:
a register, wherein
the control circuit stores, in the register, information indicating said one of program modes that was previously used and the program mode to be used to erase the data.

4. The semiconductor memory device according to claim 1, wherein
the control circuit is configured to execute a pre-read operation on the memory transistors to determine the distribution pattern.

5. The semiconductor memory device according to claim 1, wherein
the command is an erase command, and
the control circuit determines the program mode to be used to erase the data based on a prefix command followed by the erase command.

6. The semiconductor memory device according to claim 1, wherein
the program modes include a first mode in which a first number of bits can be programed into each of the memory transistors and a second mode in which a second number of bits can be programed into each of the memory transistors,
the first number is greater than or equal to 1, and
the second number is greater than the first number.

7. The semiconductor memory device according to claim 6, wherein
the control circuit is configured to determine, as the pre-program voltage:
a first voltage when said one of program modes that was previously used is the first mode and the program mode to be used to erase the data is the second mode, and
a second voltage when said one of program modes that was previously used is the second mode and the program mode to be used to erase the data is the first mode, the first voltage being higher than the second voltage.

8. The semiconductor memory device according to claim 6, wherein
the control circuit is configured to determine, as the erase voltage:
a first voltage when said one of program modes that was previously used is the first mode and the program mode to be used to erase the data is the second mode, and
a second voltage when said one of program modes that was previously used is the second mode and the program mode to be used to erase the data is the first mode, the first voltage being lower than the second voltage.

9. The semiconductor memory device according to claim 6, wherein
the first mode is a Single-Level Cell (SLC) mode, and the second mode is a Quad-Level Cell (QLC) mode.

10. The semiconductor memory device according to claim 1, wherein
the program modes include a SLC mode, a Triple-Level Cell (TLC) mode, and/or a Quad-Level Cell (QLC) mode.

11. A method performed by a semiconductor memory device that includes:
a bit line,
a plurality of memory transistors electrically connected to the bit line,
a source line electrically connected to the memory transistors, and
a word line electrically connected to a gate electrode of one of the memory transistors, the method comprising:
upon receipt of a command for erasing data stored in the memory transistors, determining
one of program modes that was previously used to write or erase data in the memory transistors based on a distribution pattern of threshold voltages of the memory transistors, and
one of the program modes to be used to erase the data; and
generating a pre-program voltage to be applied to the word line and an erase voltage to be applied to at least one of the bit line and the source line based on said one of program modes that was previously used and the program mode to be used to erase the data.

12. The method according to claim 11, wherein
the distribution pattern is an erase distribution pattern in which data was erased using one of the program modes or a write distribution pattern in which data was written using one of the program modes.

13. The method according to claim 11, further comprising:
storing, in a register, information indicating said one of program modes that was previously used and the program mode to be used to erase the data.

14. The method according to claim 11, further comprising:
executing a pre-read operation on the memory transistors to determine the distribution pattern.

15. The method according to claim 11, wherein
the command is an erase command, and
the program mode to be used to erase the data is determined based on a prefix command followed by the erase command.

16. The method according to claim 11, wherein
the program modes include a first mode in which a first number of bits can be programed into each of the memory transistors and a second mode in which a second number of bits can be programed into each of the memory transistors,
the first number is greater than or equal to 1, and
the second number is greater than the first number.

17. The method according to claim 16, wherein
the pre-program voltage is either
a first voltage when said one of program modes that was previously used is the first mode and the program mode to be used to erase the data is the second mode, or
a second voltage when said one of program modes that was previously used is the second mode and the program mode to be used to erase the data is the first mode, the first voltage being higher than the second voltage.

18. The method according to claim 16, wherein
the erase voltage is either
a first voltage when said one of program modes that was previously used is the first mode and the program mode to be used to erase the data is the second mode, or
a second voltage when said one of program modes that was previously used is the second mode and the program mode to be used to erase the data is the first mode, the first voltage being lower than the second voltage.

19. The method according to claim 16, wherein
the first mode is a Single-Level Cell (SLC) mode, and the second mode is a Quad-Level Cell (QLC) mode.

20. The method according to claim 11, wherein
the program modes include a SLC mode, a Triple-Level Cell (TLC) mode, and/or a Quad-Level Cell (QLC) mode.
